(19) United States
(12) Patent Application Publication
(10) Pub. No.: US 2004/0041519 A1
(43) Pub. Date: Mar. 4, 2004

(54) Electroluminescence light emitting display system

(75) Inventors: Kimitaka Watanabe, Tokyo (JP); Hiroyuki Yamanaka, Higashikatsushika-gun (JP)

Correspondence Address: STAAS & HALSEY LLP, SUITE 700, 1201 NEW YORK AVENUE, N.W., WASHINGTON, DC, 20005, US

(73) Assignee: Tomy Company, Ltd., Tokyo (JP)

(21) Appl. No.: 10/637,590

(22) Filed: Aug. 11, 2003

(30) Foreign Application Priority Data
Aug. 30, 2002 (JP) 2002-254617
Apr. 25, 2003 (JP) 2003-122729

(51) Int. Cl. H05B 33/08

(52) U.S. Cl. 313/506; 313/503; 313/493

(57) ABSTRACT

An electroluminescence light emitting display system has: an electroluminescence light emitting sheet which has: an electrode section having an electrode pair including first and second electrodes which are electrically separated from each other with a spacing region, and an electroluminescence light-emitting layer provided above a front surface side of the electrode section; and a voltage application unit for applying a predetermined voltage between the first and second electrodes of the electrode pair, wherein the electroluminescence light-emitting layer with a predetermined shape corresponding to a desired chart for light-emitting is placed on a front surface side of the electrode section, and an electrically conductive material is placed on a front surface side of the electroluminescence light-emitting layer, to allow a portion of the electroluminescence light-emitting layer which is overlapped with the electrically conductive material, emitting light by applying the predetermined voltage to the electrode section by the voltage application unit.

### BACKGROUND OF THE INVENTION

1. Field of the Invention

The present invention relates to an electroluminescence light emitting display system.

2. Description of Related Art

An electroluminescence material, hereinafter, which may be referred to EL material simply, is known as one of light emitting materials. Various types of EL light emitting sheets have been developed and put to practical use. The EL light emitting sheet is generally formed by laminating a first electrode, a light-emitting layer, an insulating layer, i.e., a light reflecting layer, a second electrode and a protective layer, i.e., a top coating layer, in order. Generally, by applying an alternating voltage (AC voltage) between the fist electrode and the second electrode, a fluorescent material, i.e., EL light emitting elements, in the light-emitting layer emits light.

As another type of EL light emitting sheet, one having peculiar operation and effects is known (see, for example, Patent Document 1: Japanese Patent Laid-Open Publication No. Hei 8-153582). The EL light emitting sheet is formed by laminating an electrode section, an insulating layer and a light-emitting layer in order. The electrode section includes a plurality of electrode pairs each of which have a first electrode and a second electrode, which are formed like a comb. Then, an electrically conductive material in arbitrary shape is formed on the light-emitting layer as a film and the film is dried to be formed as a display electrode. Thereby, the parts in the light-emitting layer on which the display electrode is formed as a film emit light. In the EL light emitting sheet, a display electrode having a shape corresponding to the taste of a user can be formed, and then a desired light emission shape can be obtained.

In the above-described EL light emitting sheet, because the light-emitting layer is formed on the entirety of the front surface side of the electrode section, much expensive EL light emitting material is required. As a result, the EL light emitting display system using such an EL light emitting sheet becomes also expensive.

### SUMMARY OF THE INVENTION

The present invention has been developed in view of the above-described circumstances.

An object of the invention is to provide an EL light emitting display system which is relatively not expensive.

In accordance with a first aspect of the present invention, the electroluminescence light emitting display system comprises:

an electroluminescence light emitting sheet which comprises: an electrode section comprising an electrode pair including first and second electrodes which are electrically separated from each other with a spacing region, and an electroluminescence light-emitting layer provided above a front surface side of the electrode section; and

a voltage application unit for applying a predetermined voltage between the first and the second electrodes of the electrode pair,

wherein the electroluminescence light-emitting layer with a predetermined shape corresponding to a desired chart for light-emitting is placed on a front surface side of the electrode section, and an electrically conductive material is placed on a front surface side of the electroluminescence light-emitting layer, to allow a portion of the electroluminescence light-emitting layer which is overlapped with the electrically conductive material, emitting light by applying the predetermined voltage to the electrode section by the voltage application unit.

Here, the term “chart” includes characters, figures, diagrams, symbols, combinations thereof and the like. “EL light-emitting layer” and “conductive layer” are provided, for example, by a user or by a manufacturer to agree to user's demands, through applying, printing or the like. As the conductive layer, indium tin oxide (ITO) film, antimony tin oxide (ATO) film or the like can be used.

According to the electroluminescence light emitting display system having such a structure, the amount of EL light-emitting elements which is expensive can be reduced because the EL light-emitting layer is regionally provided to a part corresponding to a chart which the user wishes to draw or represent. As a result, it is possible to realize a cheap EL light emitting display system.

In the electroluminescence light emitting display system, the electroluminescence light-emitting layer and the electrically conductive material may be formed as a body sheet, which is placed on a front surface of the electrode section.

According to the electroluminescence light emitting display system having such a structure, only a work is required for placing the EL light-emitting layer and the electrically conductive material on the electrode section because they are formed as a body sheet. As a result, it is possible to produce such an electroluminescence light emitting display system having a user's desired chart for light-emitting easily.

In accordance with a second aspect of the present invention, the electroluminescence light emitting display system comprises:

an electrode section which comprises an electrode pair including first and second electrodes which are electrically separated from each other with a spacing region;

a first electroluminescence light-emitting layer which has a predetermined shape and is provided on a front surface of the electrode section;

an electrically conductive material layer which has a predetermined shape and is placed on a front surface of the first electroluminescence light-emitting layer, at least a portion of the electrically conductive material layer being overlapped with the first electroluminescence light-emitting layer; and

a voltage application unit for applying a predetermined voltage between the first and the second electrodes of the electrode pair,

wherein a portion of the first electroluminescence light-emitting layer, which is overlapped with the electrically conductive material layer, emits light by applying the predetermined voltage to the electrode section by the voltage application unit.

In the electroluminescence light emitting display system, the first electroluminescence light-emitting layer and the electrically conductive material layer may be formed as a body sheet.

In the electroluminescence light emitting display system, the electrically conductive material layer may comprise any one of ITO, ATO, electrically conductive coating material, and electrically conductive ink.

In the electroluminescence light emitting display system, the first electroluminescence light-emitting layer may be placed on the front surface of the electrode section by coating or printing.

In the electroluminescence light emitting display system, the first electroluminescence light-emitting layer is provided on the front surface of the electrode section through a waterproof layer.

In accordance with a third aspect of the present invention, the electroluminescence light emitting display system comprises:

an electrode section which comprises an electrode pair including first and second electrodes which are electrically separated from each other with a spacing region;

a first electroluminescence light-emitting layer, which has a predetermined shape and is provided in a first region of a front surface of the electrode section;

an electrically conductive material layer which has a predetermined shape and is placed on a front surface of the first electroluminescence light-emitting layer, at least a portion of the electrically conductive material layer being overlapped with the first electroluminescence light-emitting layer;

a second electroluminescence light-emitting layer which is provided in a second region of a front surface of the electrode section; and

a voltage application unit for applying a predetermined voltage between the first and the second electrodes of the electrode pair,

wherein a portion of the first electroluminescence light-emitting layer, which is overlapped with the electrically conductive material layer, emits light, and a portion of the second electroluminescence light-emitting layer on which an electrically conductive material is placed emits light, by applying the predetermined voltage to the electrode section by the voltage application unit.

According to the electroluminescence light emitting display system having such a structure, the first EL light-emitting layer, which has a predetermined shape, is regionally provided in the first region of the front surface of the electrode pair. Consequently, it is possible to reduce the amount of an expensive EL light emitting element to be used, and realize a cheap EL light emitting display system.

On the other hand, in the second region of the front surface of the electrode section, it is possible to draw a light emitting chart by applying the electrically conductive material easily. Moreover, it is also possible to remove the applied electrically conductive material easily. Consequently, the repeating drawing of charts for light emitting can easily be realized.

In the electroluminescence light emitting display system, the first electroluminescence light-emitting layer and the electrically conductive material layer may be formed as a body sheet.

In the electroluminescence light emitting display system, the electrically conductive material layer may include any one of ITO, ATO, electrically conductive coating material, and electrically conductive ink.

In the electroluminescence light emitting display system, the first electroluminescence light-emitting layer may be placed on the front surface of the electrode section by coating or printing.

In the electroluminescence light emitting display system, the second electroluminescence light-emitting layer is provided in the second region on the front surface of the electrode section through a waterproof layer.

In the electroluminescence light emitting display system, a top coat layer is provided on the front surface of the second electroluminescence light-emitting.

### BRIEF DESCRIPTION OF THE DRAWINGS

The present invention will become more fully understood from the detailed description given hereinafter and the accompanying drawings which are given by way of illustration only, and thus are not intended as a definition of the limits of the present invention, and wherein;

FIG. 1 is a perspective view of the EL light emitting display system according to the first embodiment of the present invention;

FIG. 2 is an exploded perspective view of the electroluminescence light emitting display system for explaining each layer of the EL light emitting sheet;

FIG. 3A is a partially enlarged sectional view of a fixed drawing region of the EL light emitting sheets, and FIG. 3B is a partially enlarged sectional view of a free drawing region of the EL light emitting sheets, respectively;

FIG. 4 is a plan view showing an electrode pattern of the EL light emitting sheet;

FIG. 5 is a functional block diagram of the EL light emitting display system according to the first embodiment;

FIGS. 6A and 6B are plan views of the EL light emitting display system according to the second embodiment of the present invention;

FIG. 7 is a control block diagram of the EL light emitting display system according to the second embodiment;

FIG. 8 is a perspective view of the EL light emitting display system according to the third embodiment of the present invention;

FIG. 9 is a partially enlarged sectional view according to variation 1 of the EL light emitting sheet; and

FIG. 10 is a plan view showing the electrode pattern according to variation 6 of the EL light emitting sheet.

### DETAILED DESCRIPTION OF THE PREFERRED EMBODIMENTS

Hereinafter, the preferred embodiments of the present invention will be described in detail by reference to the attached drawings.

### A. EL Light Emitting Display System According to First Embodiment

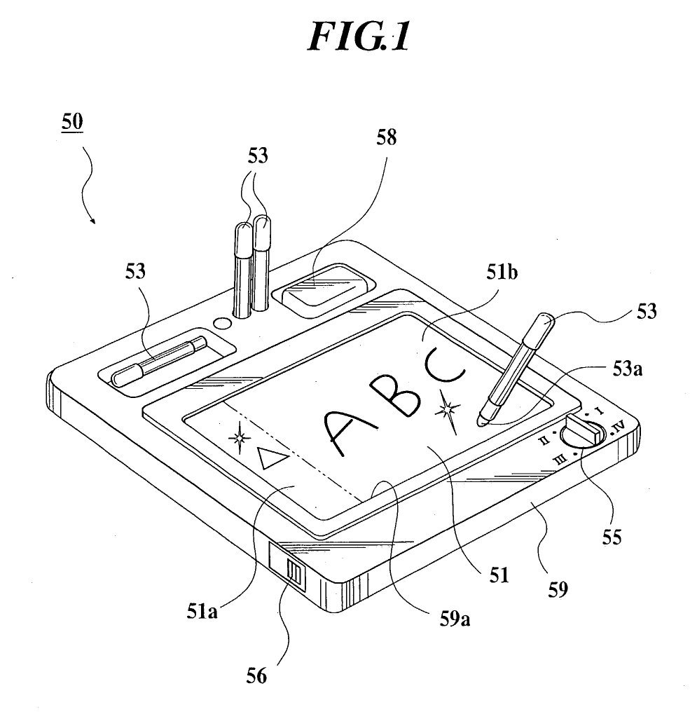

FIG. 1 is a perspective view showing the external appearance of a drawing board 50 as an example of an EL light emitting display system.

1. Whole Configuration

In the drawing board 50, a main body 59 shaped to be a board having a predetermined thickness holds an EL light emitting sheet 51 which is provided in the inside of the main body. The EL light emitting sheet 51 comprises a fixed drawing region (first region) 51a in which a predetermined character, figure or the like is drawn for emitting light, and a free drawing region (second region) 51b for drawing or representing a desired chart for light-emitting thereon freely.

In the fixed drawing region 51a, the predetermined figure of the electrically conductive material layer 40 and the first EL light-emitting layer 41 for light-emitting, which is a figure, a character or the like that a user wishes to represent or draw and does not wish to disappear, for example, the electrically conductive material layer 40 or the first EL light-emitting layer 41 of a figure, a character or the like such as “Δ” in FIG. 1, is fixedly provided. As a concrete example of a figure, a character or the like for light-emitting, provided fixedly, the user's name, user's favorite design of flower, character, or the like, can be listed.

On the other hand, in the free drawing region 51b, a user can draw, place or represent a favorite chart for light-emitting, for example, the chart for light-emitting of a character such as “ABC” or the like in FIG. 1, thereon freely by using a highlight pen 53. The chart for light-emitting drawn on the free drawing region 51b can be erased easily by an erasing member 58. The “character or the like” includes not only a character but also a figure, a symbol, and the combination thereof.

Further, the drawing board 50 comprises a change-over switch 55 for switching light-emitting modes, and a power supply switch 56.

2. How to Use

A user places a predetermined shape of the electrically conductive material layer 40 or the first EL light-emitting layer 41, for example, of a figure, a character or the like such as “Δ” in FIG. 1, which the user wishes to draw or represent and does not wish to erase, in the fixed drawing region 51a by the method as will hereinafter be described.

Then, the user draws a chart for light emitting, for example, the chart for light emitting of a character or the like such as “ABC” in FIG. 1 freely in the free drawing region 51b by using the highlight pen 53. In this case, the highlight pen 53, which has a pen point 53a made of an impregnating material impregnating an electrically conductive material 30 using electrically conductive ink including a fluorescent material therein, is used.

When a power supply switch 56 is turned on, the fluorescent display of a figure, a character or the like such as “Δ” in the fixed drawing region 51a and “ABC” in the freely drawing region 51b is performed.

There is a plurality of modes of an entirely light-emitting mode (mode I), an entirely blinking mode (mode II), a sequentially light-emitting mode (mode III) and a wavy light-emitting mode (mode IV) provided, and each mode is executed by the switching of the change-over switch 55.

3. Detailed Configuration

(1) EL Light Emitting Sheet

1) Whole Configuration

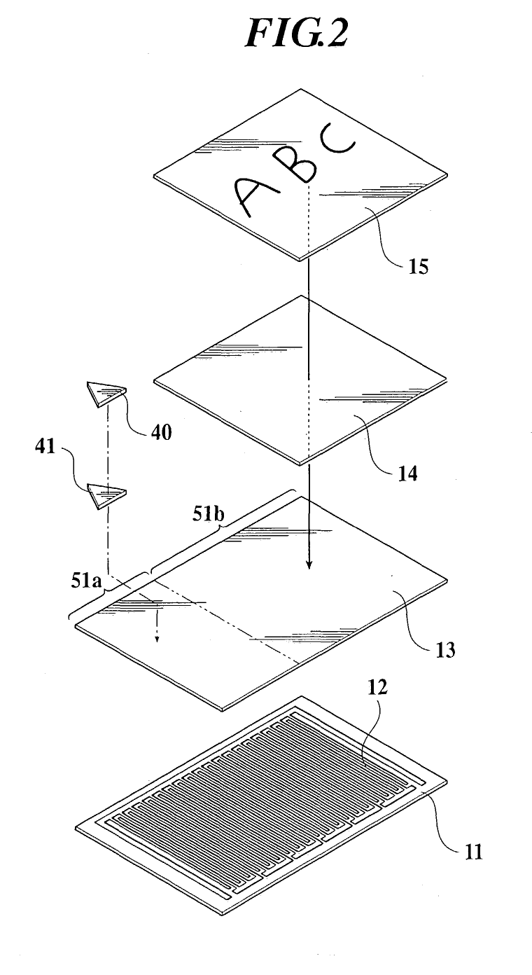

EL light emitting sheet 51 has the fixed drawing region (first region) 51a and the free drawing region 51b (second region) which are formed as a body, although it is not limited. FIG. 2 is an exploded perspective view of the electroluminescence light emitting display system for explaining each layer-of the EL light emitting sheet 51. The EL light emitting sheet 51 has a structure in which a base layer 11, an electrode layer (electrode section) 12 and a waterproof layer 13 which are layered in this order, in the fixed drawing region (first region) 51a, and a structure in which a base layer 11, an electrode layer (electrode section) 12, a waterproof layer 13, the second EL light-emitting layer 14 and a top coat layer 15 which are layered in this order, in the free drawing region (second region) 51b.

In the fixed drawing region 51a, the electrically conductive material layer 40 and the first EL light-emitting layer 41 each having a shape which is a figure, a character or the like that a user wishes to represent or draw and does not wish to disappear, are fixedly placed on the waterproof layer, for example, by the user. On the other hand, in the free drawing region 51b, a user can draw, place or represent a favorite chart for light emitting, thereon freely by using the highlight pen 53. The chart for light emitting drawn on the free drawing region 51b can be erased easily by the erasing member 58.

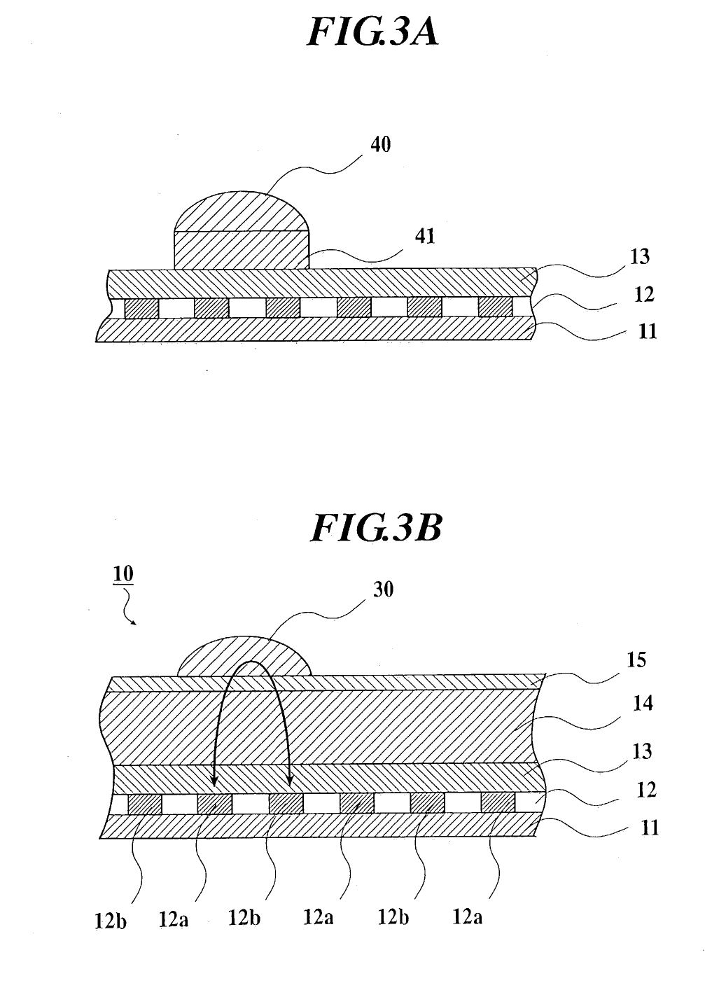

FIG. 3A shows a longitudinal section of the EL light emitting sheet 51 in the fixed drawing region 51a, and FIG. 3B shows a longitudinal section of the EL light emitting sheet in the free drawing region 51b.

Next, the base layer 11, the electrode layer (electrode section) 12, the waterproof layer 13, the first EL light-emitting layer 41 and the second EL light-emitting layer 14, the top coat layer 15, the electrically conductive material layer 40 and the electrically conductive material 30, and the like will be explained in order, as follows.

2) Base Layer 11

The base layer 11 is made of an insulating material such as polyethylene terephthalate (PET) or the like. The base layer 11 may be configured as a base film (substrate sheet). In this case, the base film is made of a transparent or opaque resin. As the resin in this case, for example, PET is used. Incidentally, the base layer 11 may be made of glass.

3) Electrode Layer 12

The electrode layer 12 having a predetermined electrode pattern is formed by depositing a metal such as copper, aluminum or the like on the base layer 11, and by performing etching or the like to the deposited metal layer. Alternatively, the electrode layer 12 is formed by depositing, for example, a pasty silver paste including silver powder, a pasty copper paste including copper powder, other electrically conductive pastes such as carbon, or the like on the base layer 11 in a predetermined pattern by the screen printing, and thereafter by performing the heat drying processing of the paste.

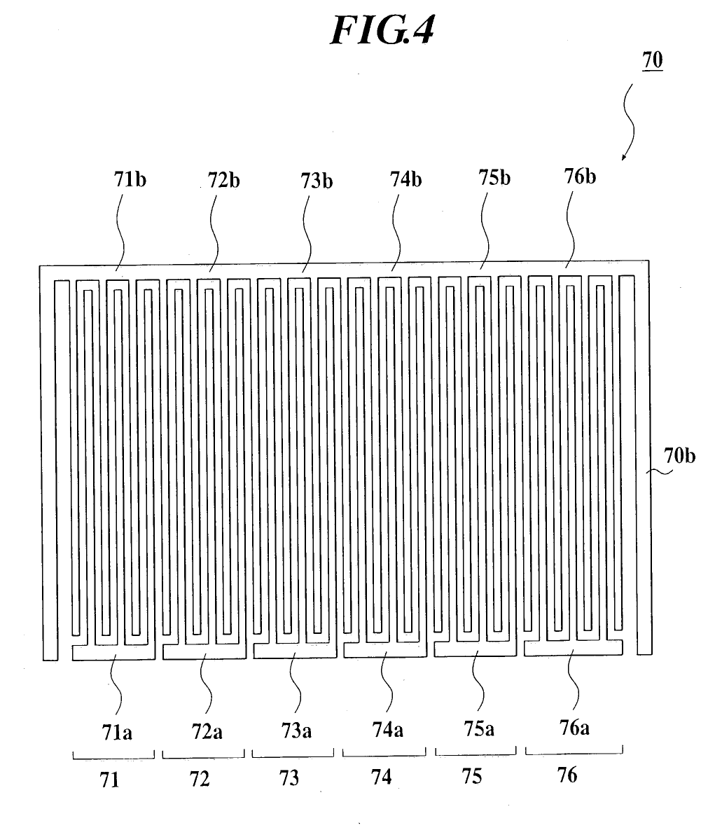

FIG. 4 is a plan view showing the outline of the electrode pattern 70 of the EL light emitting sheet 51 built in the drawing board 50. The electrode pattern 70 means the shape of the electrode layer 12 formed on the base layer 11. In the figure, an electrode 71a and an electrode 71b constitute an electrode pair 71, and the electrode 71a and 71b each has a comb-like pattern shape. The electrode pattern 70 includes six electrode pairs 71-76 having substantially the same configuration as the electrode pair 71 severally. The electrode pairs 71-76 are aligned. The upper end parts of the electrodes 71b-76b of respective electrode pairs 71-76 in the figure are connected with one another to form an electrode line (earth line) 70b which is connected to the ground. On the other hand, the electrodes 71a-76a are not connected with one another.

When a predetermined voltage (AC voltage) is applied to each of the electrodes 71a-76a, each of the electrode pairs 71-76 takes the state capable of forming a closed circuit. To put it more concretely, when the voltage is applied to all of the electrodes 71a-76a, a closed circuit is formed between the electrically conductive material layer 40 or the electrically conductive material 30, and an electrode pair through the part of the first EL light-emitting layer 41 or the second EL light-emitting layer 14 and the like, on which the electrically conductive material layer 40 or the electrically conductive material 30 is placed. However, when the voltage is applied to only a part of the electrodes 71a-76a, only the part of the electrode pair corresponding to the electrode to which the voltage is applied can form a closed circuit (the sate may be referred to as a “closed circuit formation possible state”, and a state other than the above-mentioned state may be referred to as a “closed circuit formation impossible state” in the present specification).

The gap between the first electrode 12a and the second electrode 12b which are next to each other may be, for example, about 0.1-2.0 mm, and the width of the first electrode 12a and the second electrode 12b themselves may be, for example, about 0.1-5.0 mm, which are enough for light emission only.

However, when taking into account the case of placing a chart for light emission, of a thin line which is approximately parallel to the extending direction of comb-shaped pattern electrode, or a dot-shaped chart for light emission, the gap between the first electrode 12a and the second electrode 12b which are next to each other is preferably about 0.2-0.3 mm, and the widths of the first electrode 12a and the second electrode 12b themselves are preferably about 0.2-0.5 mm.

The reason for the above-described definition of gap or width is as follows.

When the gap between the first electrode 12a and the second electrode 12b is less than 0.2 mm, there is a large possibility that a light emission (spontaneous emission) which is not negligible is created in also a region onto which no electrically conductive material layer 40 or electrically conductive material 30 is placed. When the gap is more than 0.3 mm, particularly, in a case of placing a chart of a thin line, flecks of light emission stand up. Under conditions, that is, EL sheet with a light emitting region of 140 mm×92 mm, starting voltage of 250V to 270V and current of 100 mA to 130 mA, luminance of emitted lights from two EL light emitting sheets which have gaps of 0.2 mm and 0.15 mm, respectively, were compared. As a result, the luminance of emitted lights from the EL light emitting sheet having the gap of 0.2 mm was 3±0.5 candela and that of 0.15 mm was 6±0.5 candela which was approximately twice that of 0.2 mm gap case. Therefore, it is considered that when assuming a regular use condition in an ordinary room as an industrial product, the luminance of emitted light, of 3±0.5 candela which is obtained by the gap of 0.2 mm is a lower limit.

On the other hand, when the width sizes of the first electrode 12a and the second electrode 12b themselves are less than 0.2 mm, there are problems that the luminance of emitted lights may be lowered and the productivity may deteriorate by bridge or disconnection, occurred in mass production. When the width sizes are more than 0.5 mm, there is a problem that, in a case of placing a dot-shaped chart for light emission by using a pen for drawing a thin line, a probability of AC electric field formation with another electrode is lowered because the thin chart may be within the width of one electrode. When the width sizes are not more than 0.5 mm, the probability of AC electric field formation with another electrode is increased because the probability of the placed dot-shaped chart being out of the one electrode is much larger than that of the chart being placed at the center of the one electrode.

Thus, it is possible to increase the probability of AC electric field formation, to restrain occurrence of flecks of light emission for a chart such as a character, and to form a beautiful light emitting chart.

4) Waterproof Layer 13

The waterproof layer 13 is a layer for protecting the electrode layer 12 and is made of a resin. As the resin, the following resins can be used. That is, they are, for example, a fluorocarbon resin such as a 4-fluorinated ethylene resin, fluororubber and the like; a silicon resin such as silicon rubber and the like; the other epoxy resins; an acrylic resin; a urethane resin; a polyester resin; and a resin having a high sealing property such as an ethylene-vinyl acetate copolymer and the like. These resins are cured by a method such as ultraviolet (UV) curing, infrared (IR) curing, two-liquid curing, heat curing and the like.

5) First EL Light-Emitting Layer 41, Second EL Light-Emitting Layer 14

The first EL light-emitting layer 41 and the second EL light-emitting layer 14 are made of organic or inorganic EL light-emitting elements. The EL light-emitting elements are put with being dispersed in a transparent resin binder.

As the resin binder, a resin having a high dielectric constant such as a polyester resin or the like is suitably selected. The first EL light-emitting layer 41 and the second EL light-emitting layer 14 have a thickness of about 30-40 μm, a withstanding voltage of about 50-150 V, and a dielectric constant of about 10-30. The thickness of the first EL light-emitting layer 41 and the second EL light-emitting layer 14 are preferably one and a half times as large as the diameter of an EL light emitting element or more. With such a thickness, the surfaces of the first EL light-emitting layer 41 and the second EL light-emitting layer 14 are regarded as being smooth, and for example, their surface roughness is regarded as being 30 μm or less.

The first EL light-emitting layer 41, which has a shape corresponding to the user's taste, is placed on the front surface of the waterproof layer 13 by a user coating or printing in the fixed drawing region 51a. On the other hand, the second EL light-emitting layer 14 is placed on the whole surface of the waterproof layer 13 in the free drawing region 51b before being handed over to the user.

6) Top Coat Layer 15

The top coat layer 15 is provided on the free drawing region 51b to protect the second EL light-emitting layer 14. The top coat layer 15 is laminated on the second EL light-emitting layer 14 also for improving the smoothness of the second EL light-emitting layer 14 and the removability of an electrically conductive material 30. If the second EL light-emitting layer 14 itself can secure necessary smoothness and removability, it is needless to provide the top coat layer 15 specially.

As the top coat layer 15, the following resins can be used. That is, they are, for example, a fluorocarbon resin such as a 4-fluorinated ethylene resin, fluororubber and the like; a silicon resin such as silicon rubber and the like; a polyester resin; a urethane resin and the like. Since the main object of providing the top coat layer 15 is, as described above, to smooth the surface of the second EL light-emitting layer 14 and to improve the removability, the thickness of the top coat layer 15 is enough to be a degree which makes it possible to attain the object. On the other hand, it is suitable that the top coat layer 15 is as thin as possible. The reason for this is that the more the thickness is, the more the luminous intensity of the EL light-emitting sheet 10 decreases. The thickness is practically preferable to be about 1-2 μm as the effective value. Hereupon, the “effective value” means the size of the thickness of the top coat layer 15 adhering to the uppermost part of the second EL light-emitting layer 14. It is sufficient for obtaining the thickness of about 1-2 μm as the effective value to make the coating value of the thickness about 5-8 μm. Hereupon, the “coating value” means the thickness of the protection layer 15 when the coating is performed on a surface having no irregularities.

The top coat layer 15 may be formed by gluing a film-like or sheet-like member fixedly onto the second EL light-emitting layer 14, or by adhering a flexible material member thereto.

7) Electrically Conductive Material Layer 40, Electrically Conductive Material 30

As the electrically conductive material layer 40 used in the fixed drawing region 51a, the following known materials can be used. That is, they are: indium tin oxide (ITO) and antimony tin oxide (ATO) which are used for a transparent electrode in a liquid crystal, and they are placed on the front surface of the first EL light-emitting layer 41 by coating or printing. Other electrically conductive coating material and electrically conductive ink, which are nonvolatile and transparent, can be used.

On the other hand, as the electrically conductive material 30 used in the free drawing region 51b, the following known materials can be used other than ITO film and ATO film. That is, they are: a stick type painting material such as ink, a pencil, a crayon, a pastel and the like; a sheet material having electrical conductivity (hereinafter referred to as a conductor sheet) and the like. As the stick type painting material such as the ink, the pencil, the crayon, the pastel and the like, ones including an organic or an inorganic coloring pigment may be used.

As the ink, one having the following properties is preferable. The properties are, for example, to have a surface resistance value equal to or less than 10⁶ Ω/□ in the state of being coated, to have optical transparency, and to include at least one kind of powder of the electrically conductive materials such as indium oxide, tin oxide, antimony, zinc oxide and the like. Further, as the ink, an electrically conductive polymer such as polyethylene dioxi thiophene and the like or a mixture of the electrically conductive polymer with the powder of the electrically conductive material may be used. In this case, it is possible to make the ink emit light for a long period until the removal of the ink by wiping or the like. Moreover, the electrically conductive material 30 may be composed of water or a solvent, which have a high dielectric constant. In this case, the electrically conductive material 30 can easily be removed by drying it with a dryer, or by wiping it with a tissue, a piece of gauze, a sponge and the like.

(2) Internal Circuits

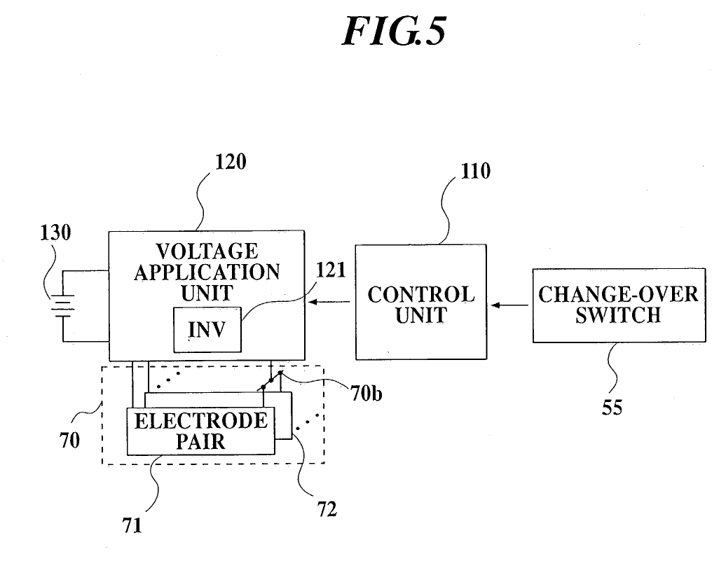

FIG. 5 is a functional block diagram of the drawing board 50. In the figure, the drawing board 50 is provided with a control unit 110 composed of a central processing unit (CPU), a random access memory (RAM), a read only memory (ROM) and the like, a battery 130 composed of dry cells, and a voltage application unit 120. The voltage application unit 120 includes an inverter circuit 121 for converting a direct-current (DC) voltage supplied from the battery 130 to an AC voltage, and a booster circuit (not shown). The voltage application unit 120 applies an effective AC voltage of about 100-300 V between the earth line 70b of the electrode pattern 70 and each of the electrode pair 71-76 according to a control signal input from the control unit 110.

The control unit 110 stores programs instructing the procedures of applying the voltage to the electrode pattern 70 into the ROM at every light emitting mode. The control unit 110 reads a corresponding program according to a mode selection signal which is input from the change-over switch 55, and outputs a control signal to the voltage application unit 120.

Then, various light emitting modes can be realized by controlling the voltage application to the electrode pairs 71-76. In the drawing board 50, an entirely light-emitting mode (mode I), an entirely blinking mode (mode II), a sequentially light-emitting mode (mode III) and a wavy light-emitting mode (mode IV) are executed by the switching of the change-over switch 55.

(3) Light-Emitting Modes

(a) Entirely Light-Emitting Mode

The entirely light-emitting mode is a mode in which an voltage is applied to all of the electrode pair 71-76 simultaneously and continuously. In other words, the mode is one in which all of the electrode pairs 71-76 are in the closed circuit formation possible state. If the electrically conductive material layer 40 and the electrically conductive material 30 are coated on all over the drawing region, the whole surface of the drawing region continuously emits light.

(b) Entirely Blinking Mode

The entirely blinking mode is a mode in which a voltage is applied to all of the electrode pairs 71-76 simultaneously and intermittently. In other words, the mode is one in which all of the electrode pairs 71-76 simultaneously take the closed circuit formation possible state or the closed circuit formation impossible state alternately at predetermined time intervals. If the electrically conductive material layer 40 and the electrically conductive material 30 are coated on all over the drawing region, the whole surface of the drawing region intermittently emits light.

(c) Sequentially Light-Emitting Mode

The sequentially light-emitting mode is a mode in which a voltage is accumulatively applied to the electrode pairs 71-76 in the order of their arrangement. In other words, the mode is one in which the electrode pairs 71-76 which have been in the closed circuit formation impossible state sequentially become the closed circuit formation possible state at predetermined time intervals. If the electrically conductive material layer 40 and the electrically conductive material 30 are coated on all over the drawing region, an area part of one sixth of the whole area of the drawing region sequentially emits light (since there are six electrode pairs), and the area emitting light gradually increases. Incidentally, after all of the electrode pairs have become the closed circuit formation possible state, the application of the voltage to all of the electrode pairs 71-76 is stopped after a predetermined time to make all of the electrode pairs 71-76 be in the closed circuit formation impossible state. Thereby, the electrode pairs 71-76 return to the initial state, and the execution of the sequential light-emitting is repeated.

(d) Wavy Light-Emitting Mode

The wavy light-emitting mode is a mode in which a voltage is intermittently applied to the electrode pairs 71-76 in the order of their arrangement. In other words, the mode is one in which each of the electrode pairs 71-76 repeatedly transits the closed circuit formation possible state and the closed circuit formation impossible state with a predetermined time lag. If the electrically conductive material layer 40 and the electrically conductive material 30 are coated on all over the drawing region, each area part of one sixth of the whole area of the drawing region sequentially emits light and does not emit light, and consequently the parts emitting light operates to appear as if they were moving while waving.

4. Advantageous Effects

As described above, in the drawing board 50, the first EL light-emitting layer 41, which has a shape corresponding a user's taste, is regionally provided. Consequently, it is possible to reduce the amount of an expensive EL light emitting element to be used, and realize a cheap EL light emitting display system.

Further, in the free drawing region 51b, it is possible to draw a light emitting chart by applying the electrically conductive material 30 easily with the highlight pen 53. Moreover, it is also possible to remove the coated electrically conductive material 30 easily. Consequently, the repeating drawing of charts for light emitting can easily be realized.

Furthermore, a plurality of electrode pairs are formed in the EL light emitting sheet, and the control unit 110 controls the execution of the voltage application to each electrode pair. Thereby, light-emitting modes for light emitting charts can variously be changed, which makes it possible to realize interesting light emission together with the aid of the variation of the places where the electrically conductive material 30 are coated.

Further, the electrode layer 12 of the EL light emitting sheet 10 is, as described above, formed by deposition of a metal. When it is intended to form the electrode layer 12 by, for example, deposition of aluminum, the thickness of the electrode layer 12 is preferably about 300-1,000 Å (10⁻¹⁰ m), more preferably about 400-800 Å (10⁻¹⁰ m). Since the electrode layer 12 is very thin and is formed by deposition of aluminum, if a user, for example, scratches the EL light emitting sheet with a cutter or strikes a nail, only a part of the electrode layer 12 contacting with the cutter or the nail, is melted almost simultaneously with the shortage. Consequently, the worst case where the whole of the electrode layer 12 is shorted is not generated, and the user does not receive electric shock.

Incidentally, it is needless to say that the EL light emitting display system may be applied to other toys. In that case, the toys are not limited to the ones aiming to draw the light emitting charts like the EL light emitting display toys (for example, the drawing board 50), but the toys may be ones incorporating the EL light emitting display system as a part of them.

### B. Light Emitting Display System According to Second Embodiment

1. Whole Configuration

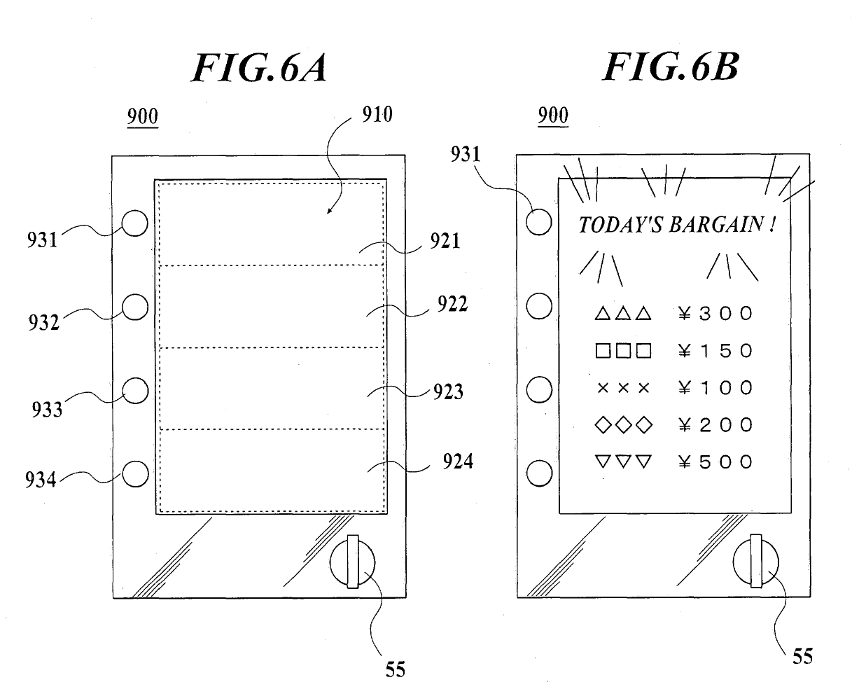

A signboard 900 according to a variation of the EL light emitting system is shown in FIGS. 6A and 6B. The signboard 900 is provided with an EL light emitting sheet 910 therein. The EL light emitting sheet 910 includes rectilinearly arranged four electrode pairs formed by depositing aluminum on a base layer 11. Buttons 931, 932, 933 and 934 (hereinafter referred to as buttons 930 comprehensively) corresponding to each of the electrode pairs 921, 922, 923 and 924 (hereinafter referred to as electrode pairs 920 comprehensively) are arranged on one side of a drawing screen, i.e., the top surface of the top coat layer of the EL light emitting sheet. The buttons 930 are made to be toggle switches. The buttons 930 are configured to output pushed signals when the buttons 930 are pushed down.

In the signboard 900, the portion corresponding to the electrode pair 921 of the EL light emitting sheet 910 is the fixed drawing region, and the portion corresponding to the electrode pair 922-924 of the EL light emitting sheet 910 is the free drawing region.

The EL light emitting sheet 910 and the signboard 900 have the same configuration as those of the EL light emitting sheet 51 and the drawing board 50 except the arrangement configuration of the electrode pairs.

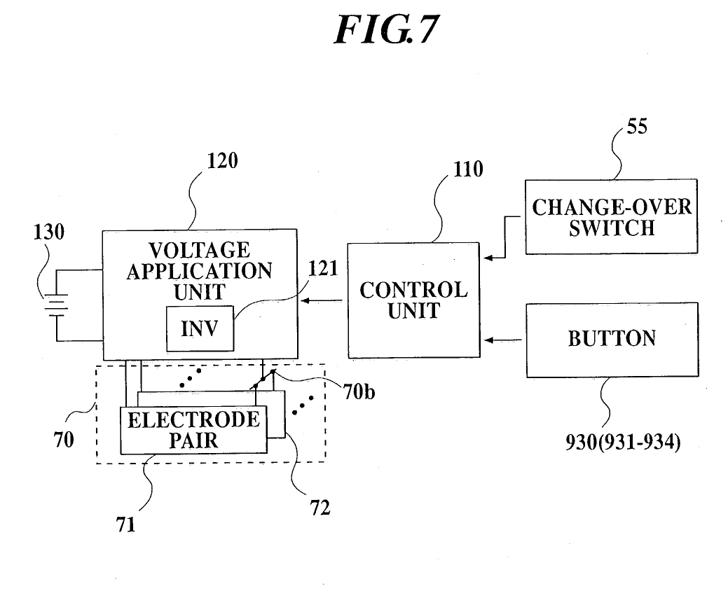

FIG. 7 is a control block diagram of the signboard 900. The configuration of the signboard is substantially the same as that of the drawing board 50 shown in FIG. 1. The configuration of the signboard is provided with the buttons 930. In FIG. 7, the control unit 110 selects and decides a region where light is to be emitted, that is, an electrode pair to which a predetermined voltage is applied on the basis of the pushed signal inputted from the buttons 930. For example, when the buttons 931 and 932 are pushed down, the control unit 110 selects and decides the electrode pairs 921 and 922. Then, the control unit 110 performs voltage application to the selected and decided electrode pairs 921 and 922 on the basis of the light emitting mode selected with the change-over switch 55.

FIG. 6B is a view showing an embodiment of the signboard 900 in the state in which the button 931 is pushed down. Since the electrode pair 921 is in the state of closed circuit formation possible state, the portion of the characters indicating “TODAY'S BARGAIN!”, which have been drawn with the electrically conductive material layer 40, emits light in the fixed drawing region where the electrode pair 921 is arranged.

Incidentally, the buttons 930 may be composed of change-over switches to make it possible to select light emitting modes in addition to the turning on and off, of the electrode pairs. In this case, for example, a light emitting form in which light emission is blinked in the fixed drawing region as “TODAY'S BARGAIN!” while a continuous light emission is given in the free drawing region, can be realized in FIG. 6B.

### C. EL Light Emitting Display System According to Third Embodiment

(1) Schematic Configuration

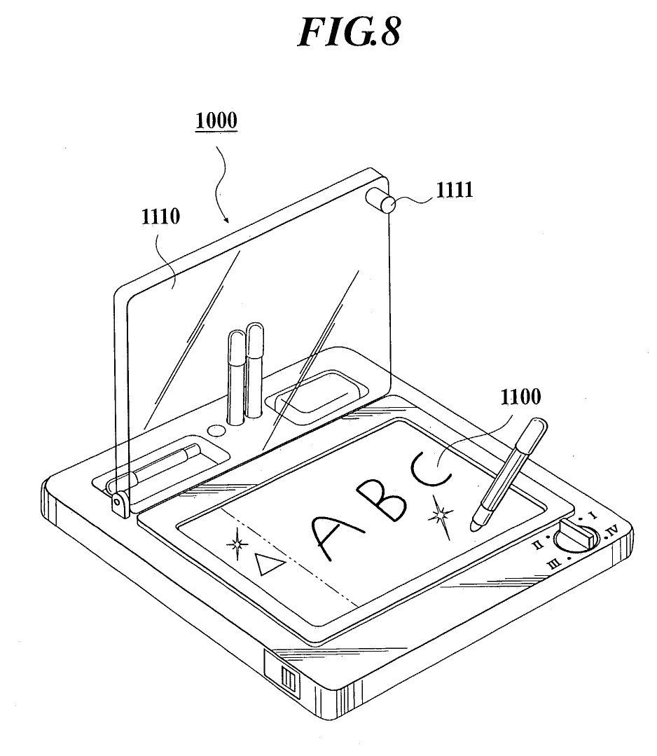

FIG. 8 is a perspective view showing an external appearance of a drawing board 1000 as an example of the EL light emitting display system.

As shown in FIG. 8, the drawing board 1000 is provided with a transparent cover 1110 on an EL light emitting sheet 1100. The cover 1110 is configured to be capable of being opened and closed. On the back side of the cover 1110, a projection 1111 is annexed. The projection 1110 is provided to turn on a power supply control switch (not shown in the figure) which is arranged on the inside of the drawing board 1000 when the cover 1110 is closed. Other configurations and the like of the EL light emitting sheet 1100 are substantially the same as those of the drawing board 50.

(2) Function and Advantageous Effect

The EL light emitting display system does not work only by turning the power supply switch 1256 on. Only when both the power supply switch 1256 and the power supply control switch are turned on, the system does work to become in a closed circuit formation possible state. Therefore, even if the liquid electrically conductive material 30 penetrates into the EL light emitting sheet 1100 to short-circuit the electrode pair, no AC current is applied to the electrode pair unless the cover 1110 is closed. Accordingly, it is possible to enhance the safety.

### D. Variations of EL Light Emitting Sheet

1. Variation 1 of EL Light Emitting Sheet

(1) Whole Configuration

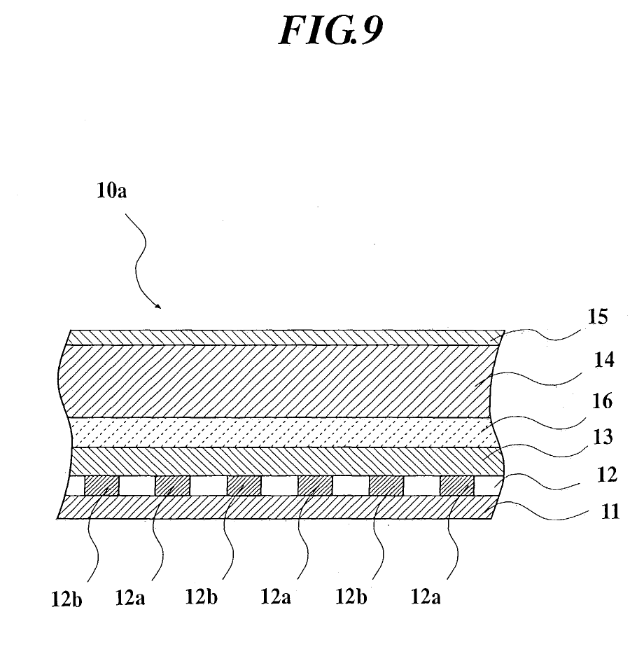

As shown in FIG. 9, the EL light emitting sheet 10a according to the variation 1 has a structure in the free drawing region in which the base layer 11, the electrode layer 12, the waterproof layer 13, the light reflecting layer 16, the second EL light-emitting layer 14 and the top coat layer 15 are laminated in this order. On the other hand, the EL light emitting sheet 10a has a structure in the fixed drawing region in which the base layer 11, the electrode layer 12, and the waterproof layer 13 are laminated in this order. The EL light emitting sheet 10a may have a structure in the fixed drawing region in which the base layer 11, the electrode layer 12, the waterproof layer 13 and top coat layer 15 are laminated in this order. Since each structure of the base layer 11, the electrode layer 12, the waterproof layer 13, the first EL light-emitting layer 41 and the second EL light-emitting layer 14, and the top coat layer 15 is substantially the same as that of the EL light emitting sheet 51 in the embodiment of the present invention, the same reference numeral as that of the sheet 51 is attached to each element and the description for them are omitted. Mainly, the light-reflecting layer 16 will be described in the following.

(2) Light-Reflecting Layer 16

The light-reflecting layer 16 is arranged between the waterproof layer 13 and the first EL light-emitting layer 41 or the second EL light-emitting layer 14. The light-reflecting layer 16 has a thickness of about 10-30 μm, a withstanding voltage of about 200-300 V, and a dielectric constant of about 30-100, preferably about 60-100.

The light-reflecting layer 16 is made by dispersing inorganic powder which is ferroelectric powder such as barium titanate or Rochelle salt, into a resin functioning as a bonding agent such as an acrylic resin or the like. Since the inorganic powder such as the ferroelectric powder is a pigment showing white, the light-reflecting layer 16 becomes white, and therefore the light-reflecting layer 16 exhibits the light-reflecting function effectively.

2. Variation 2 of EL Light Emitting Sheet

Although the waterproof layer 13 is arranged between the electrode layer 12 and the light-reflecting layer 16 in the variation 1, the waterproof layer 13 is arranged between the light-reflecting layer 16 and the first EL light-emitting layer 41 or the second EL light-emitting layer 14 in the variation 2. In this case, the top coat layer 15 are not necessarily required.

3. Variation 3 of EL Light Emitting Sheet

The EL light emitting sheet according to the variation 3 has a structure in the free drawing region in which the base layer 11, one of the first and the second electrodes, the waterproof layer 13, the other of the first and the second electrodes, the light-reflecting layer 16, and the second EL light-emitting layer 14 are laminated in this order. On the other hand, the EL light emitting sheet 10a has a structure in the fixed drawing region in which the base layer 11, one of the first and the second electrodes, the waterproof layer 13 the other of the first and the second electrodes, and the light-reflecting layer 16 are laminated in this order. In this case, the top coat layer 15 are not necessarily required, and the light-reflecting layer 16 may be omitted.

4. Variation 4 of EL Light Emitting Sheet

Variation 4 is one that a further change is given to the EL light emitting sheet 51, or one of variations 1-3. The EL light emitting sheet according to the variation 4 has a structure in which the second EL light-emitting layer 14 and/or the light-reflecting layer 16 has a permeation prevention function to water or the like, instead of or in addition to the waterproof layer 13 in the free drawing region. On the other hand, it is preferable in the fixed drawing region to coat the exposing electrodes with the waterproof layer 13, or the light-reflecting layer 16 or the top coat layer 15 having a permeation prevention function, or to perform at least the alumite processing of the exposing electrodes before placing the electrically conductive material layer 40. In this case, the top coat layer 15 are not necessarily required.

The second EL light-emitting layer 14 with the permeation prevention function is composed of, for example, an organic or inorganic EL light-emitting elements being phosphor particles or phosphorescent particles, and a transparent resin binder for fixing the EL light-emitting elements in the state of being dispersed. The variation 4 uses a resin having a waterproof property or a moisture-proof property as the resin binder. The following resins are used. That is, the resins are, for example, a fluorocarbon resin such as a 4-fluorinated ethylene resin, fluororubber and the like; a silicon resin such as silicon rubber and the like; the other epoxy resins; an acrylic resin; a urethane resin; a polyester resin; and a resin having a high sealing property such as an ethylene-vinyl acetate copolymer and the like. These resins are cured by a method such as the UV curing, the IR curing, the two-liquid curing, the heat curing and the like.

Further, as the resins constituting the light-reflecting layer 16 having the permeation prevention function, the following resins having the waterproof property or the moisture-proof property are used. The resins are, for example, a fluorocarbon resin such as a 4-fluorinated ethylene resin, fluororubber and the like; a silicon resin such as silicon rubber and the like; the other epoxy resins; an acrylic resin; a urethane resin; a polyester resin; and a resin having a high sealing property such as an ethylene-vinyl acetate copolymer and the like. These resins are cured by a method such as the UV curing, the IR curing, the two-liquid curing, the heat curing and the like.

According to the variation 4, since the light-reflecting layer 16 prevents the permeation of water and the like, the generation of electrolysis between the first electrode 12a and the second electrode 12b can be prevented. Moreover, the snapping (damage) of a wire caused by the oxidation of the first electrode 12a and the second electrode 12b can be prevented.

5. Variation 5 of EL Light Emitting Sheet

In the variation 5, the first electrode 12a and the second electrode 12b are formed on the back surface of a base film or a sheet of glass (base layer 11) which have a permeation prevention function. As the base film in this case, one made of, for example, polyethylene terephthalate (PET) is used.

According to the variation 5, since the base film or the sheet of glass prevents the permeation of water and the like from the front side, the generation of electrolysis between the first electrode and the second electrode can be prevented. Moreover, the snapping (damage) of a wire caused by the oxidation of the first electrode and the second electrode can be prevented.

Incidentally, the configuration is used in the case where the EL light emitting sheet is incorporated in a case body or the like. In the case where the EL light emitting sheet is incorporated in the case body as described above, the back surface side is generally sealed not to be exposed. Consequently, it is needless to consider the attachment of water and the like from the back surface side. If necessary, it is enough to coat the exposing electrodes with a resin having the permeation prevention function, or to perform the alumite processing of the exposing electrodes.

Incidentally, although the first electrode and the second electrode are provided on the back surface of the substrate sheet in the variation 5, the first electrode and the second electrode may be provided with putting the substrate sheet between them. In this case, it is preferable to coat the exposing electrodes with the waterproof layer 13, or the light-reflecting layer 16 or the top coat layer 15 having a permeation prevention function, or to perform the alumite processing of the exposing electrodes.

6. Variation 6 of EL Light Emitting Sheet

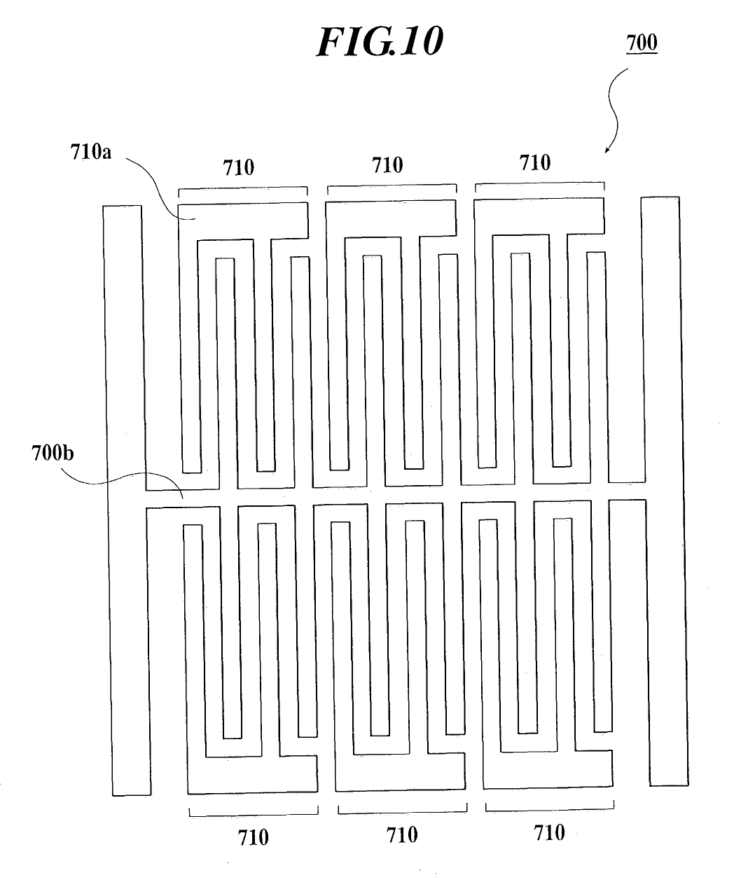

FIG. 10 shows the outline of the electrode pattern of the variation 6. In the figure, the electrode pattern 700 is a two dimensional arrangement composed of six comb-shaped electrode pairs 710 in all, three of which are arranged at the upper row in the right and left direction in the figure, and the other three of which are arranged at the lower row in the right and left direction in the figure. Moreover, the electrode pairs 710 are arranged so that the electrodes of each electrode pair are engaged in the upper and lower direction in the figure. Then, the electrode end of the earth side electrode of each electrode pair is integrally formed as an earth line 700b between the upper row electrode pairs and the lower electrode pairs of the two rows. By means of the electrode pattern 700, a wide variety of light emitting patterns can be formed with the six electrode pairs in all.

Furthermore, owing to the arrangement of the earth line 700b between the upper row electrode pairs and the lower row electrode pairs of the two rows, the gap of the upper row electrode pairs and the lower row electrode pairs can be narrowed. That is, if a displacement side electrode 710a is arranged between the upper row electrode pairs and the lower row electrode pairs of the two rows, it is impossible to connect the upper row electrode 710a and the lower row electrode 710a, and then it is necessary to arrange them with a predetermined space between them. Consequently, the gap between the upper row and the lower row of the two rows becomes wide, and the gap becomes clear in some light emission patterns. On the other hand, if the earth line 700b is arranged at the center, it becomes possible to remove, or at least to reduce, the defect as above.

### E. Other Variations of the Present Invention

(1) It is preferable to contain organic or inorganic colored pigment in the waterproof layer 13 of the EL light emitting sheet, to make the electrode pattern invisible from the front side by coloring. Such coloring enables not only making the electrode pattern invisible from the front side but also widening the range of choice for design from the front side. In a case of providing the light-reflecting layer 16, it is required to arrange the light-reflecting layer 16 near the first EL light-emitting layer 41 and the second EL light-emitting layer 14 in comparison with the waterproof layer 13.

(2) In the variation 2 of EL light emitting display system, a projection 1111 is annexed on the back side of the cover 1110, and when the cover 1110 is closed, the system works to become in a closed circuit formation possible state. However, opening and closing of the cover 1110 may be detected by any one of appropriate mechanical, electrical and optical manners, to become in a closed circuit formation possible state only when the cover 1110 is closed. Alternatively, a structure in which the power supply switch 1256 is locked during the cover 1110 is opened, may also be used.

The entire disclosure of Japanese Patent Application No. Tokugan 2002-251617 which was filed on Aug. 30, 2002, and Japanese Patent Application No. Tokugan 2003-122729 which was filed on Apr. 25, 2003, including specification, claims, drawings and summary are incorporated herein by reference in its entirety.

What is claimed is:

1. An electroluminescence light emitting display system comprising:
an electroluminescence light emitting sheet which comprises: an electrode section comprising an electrode pair including first and second electrodes which are electrically separated from each other with a spacing region, and an electroluminescence light-emitting layer provided above a front surface side of the electrode section; and
a voltage application unit for applying a predetermined voltage between the first and the second electrodes of the electrode pair,
wherein the electroluminescence light-emitting layer with a predetermined shape corresponding to a desired chart for light-emitting is placed on a front surface side of the electrode section, and an electrically conductive material is placed on a front surface side of the electroluminescence light-emitting layer, to allow a portion of the electroluminescence light-emitting layer which is overlapped with the electrically conductive material, emitting light by applying the predetermined voltage to the electrode section by the voltage application unit.

2. The electroluminescence light emitting display system as claimed in claim 1, wherein the electroluminescence light-emitting layer and the electrically conductive material are formed as a body sheet, which is placed on a front surface of the electrode section.

3. An electroluminescence light emitting display system comprising:
an electrode section which comprises an electrode pair including first and second electrodes which are electrically separated from each other with a spacing region;
a first electroluminescence light-emitting layer which has a predetermined shape and is provided on a front surface of the electrode section;
an electrically conductive material layer which has a predetermined shape and is placed on a front surface of the first electroluminescence light-emitting layer, at least a portion of the electrically conductive material layer being overlapped with the first electroluminescence light-emitting layer; and
a voltage application unit for applying a predetermined voltage between the first and the second electrodes of the electrode pair,
wherein a portion of the first electroluminescence light-emitting layer, which is overlapped with the electrically conductive material layer, emits light by applying the predetermined voltage to the electrode section by the voltage application unit.

4. The electroluminescence light emitting display system as claimed in claim 3, wherein the first electroluminescence light-emitting layer and the electrically conductive material layer are formed as a body sheet.

5. The electroluminescence light emitting display system as claimed in claim 3, wherein the electrically conductive material layer comprises any one of ITO, ATO, electrically conductive coating material, and electrically conductive ink.

6. The electroluminescence light emitting display system as claimed in claim 3, wherein the first electroluminescence light-emitting layer is placed on the front surface of the electrode section by coating or printing.

7. The electroluminescence light emitting display system as claimed in claim 3, the first electroluminescence light-emitting layer is provided on the front surface of the electrode section through a waterproof layer.

8. An electroluminescence light emitting display system comprising:
an electrode section which comprises an electrode pair including first and second electrodes which are electrically separated from each other with a spacing region;
a first electroluminescence light-emitting layer, which has a predetermined shape and is provided in a first region on a front surface of the electrode section;
an electrically conductive material layer which has a predetermined shape and is placed on a front surface of the first electroluminescence light-emitting layer, at least a portion of the electrically conductive material layer being overlapped with the first electroluminescence light-emitting layer;
a second electroluminescence light-emitting layer which is provided in a second region on a front surface of the electrode section; and
a voltage application unit for applying a predetermined voltage between the first and the second electrodes of the electrode pair,
wherein a portion of the first electroluminescence light-emitting layer, which is overlapped with the electrically conductive material layer, emits light, and a portion of the second electroluminescence light-emitting layer on which an electrically conductive material is placed emits light, by applying the predetermined voltage to the electrode section by the voltage application unit.

9. The electroluminescence light emitting display system as claimed in claim 8, wherein the first EL light-emitting layer and the electrically conductive material layer are formed as a body sheet.

10. The electroluminescence light emitting display system as claimed in claim 8, wherein the electrically conductive material layer comprises any one of ITO, ATO, electrically conductive coating material, and electrically conductive ink.

11. The electroluminescence light emitting display system as claimed in claim 8, wherein the first electroluminescence light-emitting layer is placed on the front surface of the electrode section by coating or printing.

12. The electroluminescence light emitting display system as claimed in claim 8, the second electroluminescence light-emitting layer is provided in the second region on the front surface of the electrode section through a waterproof layer.

13. The electroluminescence light emitting display system as claimed in claim 8, wherein a top coat layer is provided on the front surface of the second electroluminescence light-emitting.
